(19) United States
(12) Patent Application Publication
(10) Pub. No.: US 2022/0246849 A1
(43) Pub. Date: Aug. 4, 2022

(54) METHOD FOR DEPOSITING AN ELECTRON INJECTION LAYER

(71) Applicant: ISORG, Limoges CEDEX 3 (FR)

(72) Inventors: François FLAMEIN, GRENOBLE (FR); Mylène LEBORGNE, GRENOBLE (FR); Elodie TESTARD, GRENOBLE (FR); David GUILLERMARD, GRENOBLE (FR)

(21) Appl. No.: 17/628,031

(22) PCT Filed: Jul. 8, 2020
(86) PCT No.: PCT/EP2020/069179

§ 371 Date: Jan. 18, 2022

(30) Foreign Application Priority Data
Jul. 19, 2019 (FR) FR1908248
Mar. 31, 2020 (FR) FR2003198

(51) Int. Cl. H01L 51/00

(52) U.S. Cl. CPC H01L 51/0007; H01L 51/5088

(57) ABSTRACT

A method of forming a layer from ink on a substrate, includes the steps of: depositing an ink volume with a slot-die coating device; first drying; and second drying.

The present patent application claims the priority benefit of French patent application FR20/03198 which is herein incorporated by reference.

### FIELD

The present disclosure generally concerns inks for optoelectronic components and more particularly methods of deposition of such inks.

### BACKGROUND

Inks made up of polyethylenimine (PEI) and ethoxylated polyethylenimine (PEIE) are particularly used in image sensors and more particularly at the surface of the electrodes of such sensors to modify the work function of said electrodes.

### SUMMARY

There is a need to improve solutions of inks made up of PEI or PEIE, and more particularly the methods of forming layers from such solutions.

An embodiment overcomes all or part of the disadvantages of known methods.

An embodiment provides a method of forming a layer, from ink, on a substrate, comprising the steps of:
deposition of an ink volume with a slot-die coating device;
first drying; and
second drying.

According to an embodiment, the substrate is an electrode.

According to an embodiment, the first drying is performed in a vacuum chamber.

According to an embodiment, the method comprises, before the deposition step, a step of surface treatment of the substrate with an atmospheric plasma, a vacuum plasma, by reactive ion etching or by corona treatment.

According to an embodiment, the ink comprises a solvent and a polymer.

According to an embodiment, the solvent is selected among butanol, ethylene glycol, propylene glycol methyl ether acetate, and dimethylsulfoxide.

According to an embodiment, the polymer is selected among a polyethylenimine, an ethoxylated polyethylenimine, a perfluoroanthracene, and one or a plurality of conjugated thiols.

According to an embodiment, the polymer has a volume concentration in the ink in the range from 0.001% to 0.1%, preferably in the range from 0.01% to 0.04%.

According to an embodiment, the polymer has a molar mass in the range from 1 kg/mol to 1,000 kg/mol, preferably in the range from 20 kg/mol to 200 kg/mol.

According to an embodiment, the layer has a thickness, called wet, at the end of the deposition step in the range from 7 μm to 45 μm.

According to an embodiment, the layer has a thickness, called dry, at the end of the second drying, in the range from 1 nm to 3 nm, preferably equal to approximately 1.5 nm.

### BRIEF DESCRIPTION OF THE DRAWINGS

The foregoing and other features and advantages of the present invention will be discussed in detail in the following non-limiting description of specific embodiments in connection with the accompanying drawings, in which:

FIG. 1 shows in a partial simplified cross-section view an example of a user interface device having transparent electrodes;

FIG. 2 shows in a partial simplified cross-section view a step of an implementation mode of a layer forming method;

FIG. 3 shows in a partial simplified cross-section view another step of an implementation mode of a layer forming method;

FIG. 4 shows in a partial simplified cross-section view still another step of an implementation mode of a layer forming method;

FIG. 5 shows in a partial simplified cross-section view still another step of an implementation mode of a layer forming method; and

FIG. 6 shows in a partial simplified cross-section view still another step of an implementation mode of a layer forming method.

### DESCRIPTION OF THE EMBODIMENTS

Like features have been designated by like references in the various figures. In particular, the structural and/or functional elements common to the different embodiments and implementation modes may be designated with the same reference numerals and may have identical structural, dimensional, and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following description, unless specified otherwise, a layer or a film is called opaque to a radiation when the transmittance of the radiation through the layer or the film is smaller than 10%. In the rest of the disclosure, a layer or a film is called transparent to a radiation when the transmittance of the radiation through the layer or the film is greater than 10%, preferably greater than 50%. According to an embodiment, for a same optical system, all the elements of the optical system which are opaque to a radiation have a transmittance which is smaller than half, preferably smaller than one fifth, more preferably smaller than one tenth, of the lowest transmittance of the elements of the optical system which are transparent to said radiation. In the rest of the disclosure, the term “useful radiation” designates the electromagnetic radiation crossing the optical system in operation.

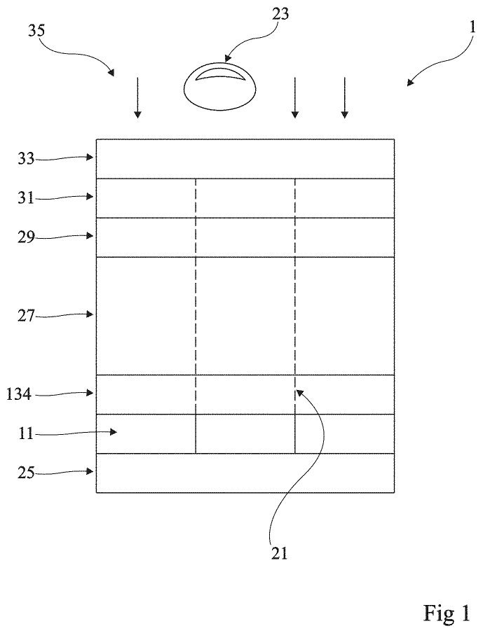

FIG. 1 shows a partial simplified cross-section view of an embodiment of a user interface device 1 with transparent electrodes.

Device 1 comprises an array of photon sensors, called photodetectors 21 (a photodetector is symbolized by dotted lines in FIG. 1), preferably capable of detecting variations of the shadow or of the image of an actuation member, for example, a finger 23. Photodetectors 21 are formed on a substrate 25 made of a transparent or translucent dielectric material, for example, of glass or plastic.

According to an embodiment, substrate 25 is an array of readout circuits for example comprising thin-film transistors (TFT).

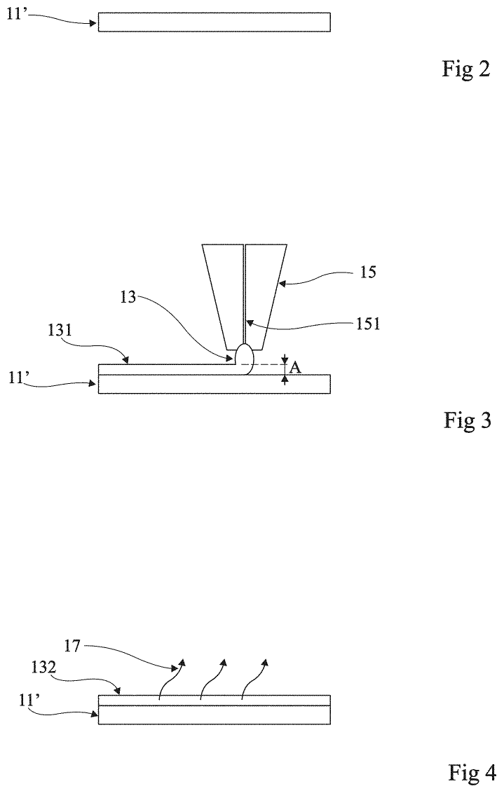

Each photodetector 21 comprises a stack, comprising, from bottom to top:
an opaque or transparent metal electrode 11 made of:
a TCO (Transparent Conductive Oxide) material, for example, indium tin oxide, gallium zinc oxide, tin oxide, fluorine tin oxide (FTC)), zinc oxide, aluminum zinc oxide, indium cadmium oxide, titanium nitride TiN, indium tin oxide (ITO), etc.;
of a metal, for example, gold, silver, lead, palladium, copper, nickel, tungsten, or chromium;
of carbon, silver, or copper nanowires;
of graphene; or
of a mixture of two or more of these materials;
an electron injection layer EIL 134 obtained from an ink according to the method described in relation with FIGS. 2 to 6;
a layer 27, called active, made of an organic material. Active layer 27 may comprise an ambipolar semiconductor material, or a mixture of an N-type semiconductor material and of a P-type semiconductor material, for example in the form of stacked layers or of a nanometer-scale intimate mixture to form a bulk heterojunction. The thickness of active layer 27 may be in the range from 50 nm to 2 μm, for example, in the order of 200 nm;
a hole injecting layer 29 (HIL) made of a heavily-doped organic semiconductor polymer, for example, a polymer known as PEDOT:PSS.
an electrode 31 forming a cathode common to all photodetectors, made up of a PEDOT:PSS type polymer or of a TCO, such as for example ITO (indium tin oxide).

Example of P-type semiconductor polymers capable of forming active layer 27 are poly(3-hexylthiophene) (P3HT), poly[N-9′-heptadecanyl-2,7-carbazole-alt-5,5-(4,7-di-2-thienyl-2′,1′,3′-benzothiadiazole)] (PCDTBT), poly[(4,8-bis-(2-ethylhexyloxy)-benzo[1,2-b;4,5-b′] dithiophene)-2,6-diyl-alt-(4-(2-ethylhexanoyl)-thieno[3,4-b] thiophene))-2,6-diyl] (PBDTTT-C), poly[2-methoxy-5-(2-ethyl-hexyloxy)-1,4-phenylene-vinylene] (MEH-PPV), or poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of N-type semiconductor materials capable of forming active layer 27 are fullerenes, particularly C60, [6,6]-phenyl-C₆₁-methyl butanoate ([60]PCBM), and [6,6]-phenyl-C₇₁-methyl butanoate ([70]PCBM).

The photoactive layer 27 of photodetectors 21 is here intended to be illuminated through an encapsulation layer and through electrode 31 and layer 29. The light radiation is schematically represented by arrows 35.

Layers 29 may be structured during, for example, a photolithography step, not shown.

Photodetector array 21 may be a passive array or an active array. For a passive array, transparent electrodes 31 may correspond to parallel rectilinear strips, and each strip may be connected to all the photodetectors 21 of a same row. For an active array, transparent electrodes 31 may correspond to a continuous layer in contact with all the photodetectors 21 of the array. As a variant, transparent electrodes 31 may be isolated from one another, photodetectors 21 being in this case independent from one another.

FIGS. 2 to 6 illustrate steps of an implementation mode of a method of forming layer 134 at the surface of electrode 11. More generally, FIGS. 2 to 6 illustrate steps of an implementation mode of a method of forming layer 134 at the surface of a substrate 11′ that may be, for example, different from an electrode.

FIG. 2 shows in a partial simplified cross-section view a step of an implementation mode of a method of forming layer 134.

More particularly, FIG. 2 illustrates an initial structure of the method. The initial structure comprises substrate 11′ (for example, electrode 11 of FIG. 1).

According to an embodiment, substrate 11′ is made of a metal oxide, selected among: zinc oxides ZnO_{X}, indium-tin oxide ITO, zinc-tin oxide ZTO, aluminum zinc oxide AZO, titanium oxides TiO_{X}, molybdenum oxides MoO_{X}, nickel oxides NiO_{X} chromium oxides CrO_{X}, copper oxides CuO_{X}, cobalt oxides CoO_{X}, iron oxides FeO_{X} manganese oxides MnO_{X} or a mixture of at least two of these oxides.

According to an embodiment, substrate 11′ is made of metal or of a metal alloy, selected from the list: gold, copper, silver, molybdenum-tantalum, molybdenum-copper.

According to an embodiment, substrate 11′ is made of a ceramic material, that is, for example, of a carbide, such as titanium carbide (TiC), a boride, a nitride such as titanium nitride (TiN), aluminum nitride (AlN), etc.

According to an embodiment, substrate 11′, more particularly the surface of substrate 11′, is first treated with a plasma at the atmospheric pressure.

The plasma treatment is for example used to make the surface of substrate 11′ hydrophilic. The plasma treatment is further use to functionalize (cause the appearing of hydroxyl and carbonyl functions) the surface of substrate 11′ and increase the surface energy of substrate 11′.

As a variant, the surface of substrate 11′ is submitted to a vacuum plasma, reactive ion etching (RIE), or corona treatment.

FIG. 3 shows in a partial simplified cross-section view another step of an implementation mode of a method of forming layer 134.

More particularly, FIG. 3 illustrates a step of deposition of a volume of a solution or ink 13 at the surface of substrate 11′ to form a layer 131.

Solution 13 is preferably formulated and made of a polymer and of a solvent.

The solvent used in the composition of solution 13 is preferably a solvent capable of uniformly dissolving or dispersing the polymer.

The solvent is for example a solvent having a boiling temperature greater than approximately 110° C. The solvent preferably is butanol, ethylene glycol, propylene glycol methyl ether acetate (PGMEA), dimethylsulfoxide (DMSO), or a combination of these solvents.

The polymer is for example selected among a polyethylenimine (PEI), an ethoxylated polyethylenimine (PEIE), a conjugated thiol, or a perfluoroanthracene.

The polymer preferably is a polyethylenimine.

The polymer has a molar mass for example in the range from 1 kg/mol to 1,000 kg/mol, preferably in the range from 20 kg/mol to 200 kg/mol.

The molar masses of the polymers are for example measured by gel permeation chromatography (GPC) particularly coupled to a light scattering detector. This technique comprises separating the molecules, here of the polymers, according to their sizes by pumping them into different columns. The light scattered at a very small angle enables to know the weight average molecular mass. The molar masses used in the present disclosure are weight average molar masses.

According to an embodiment, the polymer has a volume concentration in solution 13 in the range from 0.001% to 0.1%, preferably in the range from 0.01% to 0.04%.

The deposition of solution 13 is performed with a slot-die coating device.

The slot-die coating device comprises delivering a uniform solution over a given surface. It is in particular comprised of a head 15 provided with a slot 151.

The solution or coating material is deposited on said surface after having crossed the slot in the head. The substrate is generally set into motion, preferably rectilinearly, so that the solution is deposited all over a selected area.

The slot-die coating device is generally provided with four sub-systems:
a sub-system for measuring the flow rate of the solution in the slot;
a sub-system for positioning the head with respect to said surface;
a distribution sub-system which provides a uniform distribution of the solution across the entire width of the said surface; and
a sub-system for determining the substrate motion.

The sub-systems interact to result in the forming of a uniform coating or layer. The thickness of the deposited layer thus is a function of:
the speed of said surface relative to the slot in the head; and
the flow rate at which the solution is distributed, or speed of the solution through the slot in the head.

According to the embodiment illustrated in FIG. 3, the deposition of layer 131 is performed full plate. That is, layer 131 covers the entire upper surface of substrate 11′.

In the example of application of FIG. 1, this means that ink 13 is deposited on the material forming the underlying layer before the latter is etched to define electrodes 11.

During this step, the polymer adsorbs, by physisorption or chemisorption according to polymers, on the surface of substrate 11′, forming a monomolecular sub-layer. The solvent deposits in one or a plurality of successive sub-layers.

As an example, the PEIE and the PEI generate a physisorption mechanism at the surface of substrate 11′ while perfluoroanthracene and the conjugated thiols generate a chemisorption mechanism.

According to an embodiment, the displacement speed of head 15 relative to substrate 11′ is approximately equal to 70 mm/sec.

According to an embodiment, the flow rate of solution 13 at the outlet of slot 151 is approximately equal to 300 μL/sec.

At the end of the step illustrated in FIG. 3, layer 131, made of the polymer and of solvent, has a substantially constant thickness A, called wet, all over the surface of substrate 11′.

Thickness A is for example equal to a value in the range from 7 μm to 45 μm.

FIG. 4 shows in a partial simplified cross-section view still another step of an implementation mode of a method of forming layer 134.

More particularly, FIG. 4 illustrates a first drying step enabling the solvent to partially evaporate, which is illustrated in FIG. 4 by vapors 17, present in layer 131 of the structure obtained at the end of the steps of FIGS. 2 and 3. The step illustrated in FIG. 4 further enables to fix the polymer to the surface of substrate 11′.

The structure illustrated in FIG. 4 comprises substrate 11′ and a layer 132, originating from the layer 131 of FIG. 3. Layer 132 is a layer having its composition varying during the step illustrated in FIG. 4.

At the beginning of the step illustrated in FIG. 4, layer 132 corresponds to layer 131.

During the step illustrated in FIG. 4, the evaporation of the solvent present in layer 132 generates a decrease in the solvent content in the composition of layer 132. During this step, the solvent content in the composition of layer 132 decreases by several tens of percents.

At the end of the step illustrated in FIG. 4, the solvent content in the composition of layer 132 is for example smaller than 10%, preferably smaller than 5%. The solvent content in the composition of layer 132 at the end of the first drying is more preferably smaller than 1%.

At the end of the first drying, the thickness of layer 132 is much smaller than that of the layer 131 illustrated in FIG. 3. Layer 132 thus has a thickness in the range, for example from a few nanometers to a few tens of nanometers.

The first drying is performed in a vacuum chamber (VCD). The drying for example has a duration of approximately 2 minutes.

During this step, the chamber may be heated or not.

The steps of FIGS. 3 and 4 are preferably consecutive. The time between the two steps is for example in the range from 10 seconds to 20 seconds.

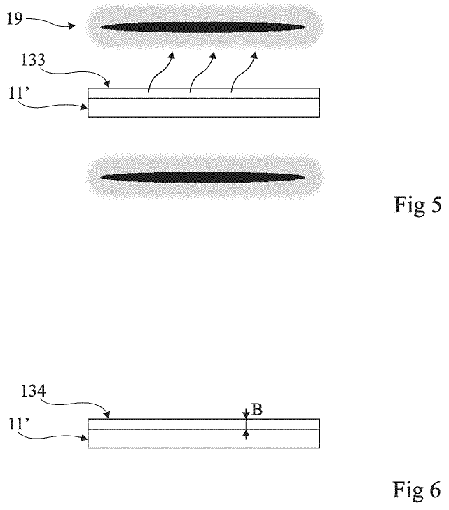

FIG. 5 shows in a partial simplified cross-section view still another step of an implementation mode of a method of forming layer 134.

More particularly, FIG. 5 illustrates a second drying step enabling to carrying on the evaporation of the solvent present in layer 132 of the structure obtained at the end of the steps of FIGS. 2 to 4.

The second drying is for example performed in a furnace 19 at a temperature for example in the range from 50° C. to 200° C., preferably in the range from 50° C. to 150° C. The temperature of the second drying is more preferably equal to approximately 100° C.

The second drying has a duration, for example, in the range from 1 minute to 120 minutes, preferably in the range from 5 minutes to 20 minutes. The duration of the second drying is more preferably equal to approximately 10 minutes.

The structure illustrated in FIG. 5 comprises substrate 11′ and a layer 133 originating from the layer 132 of FIG. 4. Layer 133 is a layer having its composition varying during the step illustrated in FIG. 5.

At the beginning of the step illustrated in FIG. 5, layer 133 corresponds to layer 132.

During the step illustrated in FIG. 5, the carrying on of the evaporation of the solvent present in layer 133 generates a decrease in the solvent content in the composition of layer 133. During this step, the solvent content in the composition of layer 133 decreases by a few percents.

At the end of the first drying, the solvent content in the composition of layer 133 is for example smaller than 1%, preferably smaller than 0.1%. The solvent content in the composition of layer 133 at the end of the second drying is more preferably smaller than 0.01%.

FIG. 6 shows in a partial simplified cross-section view still another step of an implementation mode of a method of forming layer 134.

More particularly, FIG. 6 illustrates the final structure obtained at the end of the steps of FIGS. 2 to 5.

The structure illustrated in FIG. 6 comprises substrate 11′ and the layer 134 originating from the layer 133 of FIG. 5. Layer 134 corresponds to layer 133 at the end of the step illustrated in FIG. 5.

Layer 134, made of the polymer and of solvent traces, has an approximately uniform, preferably uniform, thickness B, called dry, all over substrate 11′.

Thickness B of layer 134 is for example equal to a value in the range from 0.5 nm to 10 nm. Thickness B of layer 134 is preferably in the range from 1 nm to 3 nm. Preferably, the thickness variation of layer 134 over the entire substrate 11′ is smaller than 0.3 nm, preferably smaller than 0.1 nm.

An advantage of the described embodiments and implementation modes is the control of the thickness of the polymer deposits (PEI or PEIE in the preferred embodiments) on a substrate 11′ such as, for example, an electrode of a sensor.

Another advantage of the described embodiments and implementation modes is that they enable to form a very thin layer, which enables to increase the performance of sensors.

Still another advantage of the described embodiments and implementation modes is that they enable to provide a uniformity (in the order of one tenth of a nanometer) of the layer thickness over the entire surface of the substrate.

Still another advantage of the described embodiments and implementation modes is that they enable to ensure the repeatability of the thickness from one deposition to the other. Indeed, for given parameters (flow rate of the solution and displacement speed of the substrate), the thickness is substantially identical during a deposition or the next deposition.

Various embodiments and alterations have been described. Those skilled in the art will understand that certain features of these embodiments can be combined and other variants will readily occur to those skilled in the art. In particular, the described embodiments and implementation modes are for example not limited to the examples of dimensions and of materials mentioned hereabove.

Finally, the practical implementation of the described embodiments and variations is within the abilities of those skilled in the art based on the functional indications given hereabove.

1. A method of forming a layer, from ink, on a substrate, comprising the steps of:
deposition of an ink volume with a slot-die coating device;
first drying; and
second drying.

2. The method according to claim 1, wherein the substrate is an electrode.

3. The method according to claim 1, wherein the first drying is performed in a vacuum chamber.

4. The method according to claim 1, further comprising, before the deposition step, a step of surface treatment of the substrate by atmospheric plasma, by vacuum plasma, by reactive ion etching, or by corona treatment.

5. The method according to claim 1, wherein the ink comprises a solvent and a polymer.

6. The method according to claim 5, wherein the solvent is selected among butanol, ethylene glycol, propylene glycol methyl ether acetate, and dimethylsulfoxide.

7. The method according to claim 5, wherein the polymer is selected among a polyethylenimine, an ethoxylated polyethylenimine, a perfluoroanthracene, and one or a plurality of conjugated thiols.

8. The method according to claim 5, wherein the polymer has a volume concentration in the ink in the range from 0.001% to 0.1%.

9. The method according to claim 5, wherein the polymer has a molar mass in the range from 1 kg/mol to 1,000 kg/mol.

10. The method according to claim 1, wherein the layer has a thickness, called wet, at the end of the deposition step in the range from 7 μm to 45 μm.

11. The method according to any of claims 1 to 10 claim 1, wherein the layer has a thickness, called dry, at the end of the second drying in the range from 1 nm to 3 nm.

12. The method according to claim 5, wherein the polymer has a volume concentration in the ink in the range from 0.01% to 0.04%.

13. The method according to claim 5, wherein the polymer has a molar mass in the range from 20 kg/mol to 200 kg/mol.

14. The method according to claim 1, wherein the layer has a thickness, called dry, at the end of the second drying equal to approximately 1.5 nm.
